(19) United States
(12) Patent Application Publication
(10) Pub. No.: US 2005/0109391 A1
(43) Pub. Date: May 26, 2005

(54) Photosensitized solar cell and method of manufacturing the same

(76) Inventor: Tsuyoshi Kobayashi, Kawasaki-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/948,128

(22) Filed: Sep. 24, 2004

(30) Foreign Application Priority Data
Sep. 29, 2003 (JP) 2003-338563

(51) Int. Cl. H01L 31/00

(52) U.S. Cl. 136/263

(57) ABSTRACT

A photosensitized solar cell includes a transparent substrate, a groove formed in a surface of the transparent substrate, and having a wall surface and a bottom surface, at least a part of the wall surface being parallel to or inclined to the surface of the transparent substrate, a current collector wiring made of metal, provided on the bottom surface and wall surface of the groove, a transparent electrode layer provided in a non-groove region on the surface of the transparent substrate, a counter substrate, a conductive layer provided on the counter substrate, a semiconductor electrode provided between the conductive layer and the transparent electrode layer, and carrying a dye, and an electrolyte layer provided between the semiconductor electrode and the conductive layer.

### CROSS-REFERENCE TO RELATED APPLICATIONS

This application is based upon and claims the benefit of priority from prior Japanese Patent Application No. 2003-338563, filed Sep. 29, 2003, the entire contents of which are incorporated herein by reference.

### BACKGROUND OF THE INVENTION

1. Field of the Invention

The present invention relates to a photosensitized solar cell and a method of manufacturing the same.

2. Description of the Related Art

A general photosensitized solar cell comprises a transparent electrode which supports a semiconductor layer having a dye carried on a surface of fine particles of metal oxide, a counter electrode facing the transparent electrode, and an electrolyte layer interposed between the two electrodes.

Such a photosensitized solar cell operates in the following process. That is, an incident light coming from the transparent electrode side reaches the dye carried on the surface of the semiconductor layer, and excites this dye. The excited dye immediately hands over an electron to the semiconductor layer. On the other hand, by losing the electron, the dye is positively charged, and receives an electron from an ion which has diffused from the electrolyte layer, and is then electrically neutralized. The ion handing over the electron diffuses into the counter electrode, and receives an electron. By using the transparent electrode and counter electrode as a negative electrode and a positive electrode, respectively, the photosensitized solar cell operates as specified.

The transparent electrode is high in resistance. Therefore, when a photosensitized solar cell having a large electrode area is fabricated, its resistance cannot be ignored, and the efficiency is lowered.

To solve this problem, for example, Jpn. Pat. Appln. KOKAI Publication No. 2001-320068 proposes a technology of forming a wiring for collecting current by a metal such as aluminum on a substrate of the transparent electrode.

### BRIEF SUMMARY OF THE INVENTION

It is hence an object of the invention to present a photosensitized solar cell capable of obtaining a high energy conversion efficiency, and a method of manufacturing the same.

According to a first aspect of the present invention, there is provided a photosensitized solar cell comprising:

a transparent substrate having a groove with an inclined wall surface;

a current collector wiring made of metal, provided on the inclined wall surface of the groove;

a transparent electrode layer provided in a region other than the groove on the transparent substrate;

a semiconductor layer provided on the transparent electrode layer and current collector wiring;

a semiconductor electrode provided on the semiconductor layer, and carrying a dye;

a counter substrate;

a conductive layer provided on the counter substrate and facing the semiconductor electrode; and

an electrolyte layer provided between the semiconductor electrode and the conductive layer, and containing iodine and iodide.

According to a second aspect of the present invention, there is provided a photosensitized solar cell comprising:

a transparent substrate;

a groove formed in a surface of the transparent substrate, and having a wall surface and a bottom surface, at least a part of the wall surface being parallel to or inclined to the surface of the transparent substrate;

a current collector wiring made of metal, provided on the bottom surface and wall surface of the groove;

a transparent electrode layer provided in a non-groove region on the surface of the transparent substrate;

a counter substrate;

a conductive layer provided on the counter substrate;

a semiconductor electrode provided between the conductive layer and the transparent electrode layer, and carrying a dye; and

an electrolyte layer provided between the semiconductor electrode and the conductive layer.

According to a third aspect of the present invention, there is provided a photosensitized solar cell comprising:

a transparent substrate;

a plurality of transparent electrode layers provided on the transparent substrate,

grooves formed on the transparent substrate and between the transparent electrode layers, and having an inclined wall surface;

a current collector wiring made of metal, provided on the inclined wall surface of the groove;

a semiconductor layer which covers the transparent electrode layers and the current collector wiring;

a semiconductor particle layer provided on the semiconductor layer, and carrying a dye;

a counter substrate;

a conductive layer provided on the counter substrate, and facing the semiconductor particle layer; and

an electrolyte layer provided between the semiconductor particle layer and the conductive layer, and containing iodine and iodide.

According to a fourth aspect of the present invention, there is provided a method of manufacturing a photosensitized solar cell, comprising:

forming a transparent electrode layer on a transparent substrate;

forming a groove having an inclined wall surface on the transparent electrode layer;

forming a current collector wiring made of metal on the inclined wall surface of the groove;

forming a semiconductor layer on the groove and the transparent electrode layer;

forming a semiconductor electrode on the semiconductor layer;

carrying a dye on the semiconductor electrode;

forming a conductive layer on a counter substrate; and

forming an electrolyte layer between the semiconductor electrode and the conductive layer, and the electrolyte layer containing iodine and iodide.

### BRIEF DESCRIPTION OF THE SEVERAL VIEWS OF THE DRAWING

FIG. 1 is a sectional view showing a photosensitized solar cell according to an embodiment of the invention.

FIG. 2 is a sectional view showing a photosensitized solar cell according to another embodiment of the invention.

FIG. 3 is a sectional view showing a photosensitized solar cell according to a different embodiment of the invention.

FIG. 4 is a schematic diagram showing a process of forming a groove in a transparent substrate in a photosensitized solar cell in Example 1.

FIG. 5 is a schematic plan view showing configuration of a current collector wiring in the photosensitized solar cell in Example 1.

### DETAILED DESCRIPTION OF THE INVENTION

In the solar cell disclosed in the above-described publication, part of an electrolyte composition may pass through the transparent electrode to reach the current collector wiring, whereby the iodine contained in the electrolyte and the metal of the current collector wiring may react, and the metal may elute into the electrolyte.

Therefore, when providing a current collector wiring in a photosensitized solar cell, it is preferred to prevent the metal of the current collector wiring from reacting with the iodine in the electrolyte layer.

In an embodiment of the present invention, accordingly, a groove is provided after forming a transparent electrode layer on a transparent substrate, and a current collector wiring is formed in the groove. As a result, a surface (a principal plane) of the transparent substrate is covered with the transparent electrode layer and the current collector wiring. Further, when the current collector wiring is formed in the groove having an inclined wall surface, the current collector wiring can be arranged uniformly in the inner surface of the groove, so that a favorable conduction is maintained between the transparent electrode layer and the current collector wiring. Since a dense semiconductor layer is formed thereon, penetration of an electrolyte can be prevented by the semiconductor layer, and elution of a metal component of the current collector wiring can be avoided. The semiconductor layer is preferred to be formed in a thin film so as not to raise the electric resistance. On the other hand, when formed thinly, the semiconductor layer may peel off irregularities in the transparent electrode layer if the surface of the transparent electrode layer is rough. In the embodiment, since the transparent electrode layer and current collector wiring are formed uniformly without defects, the flatness of the surfaces of the transparent electrode layer and current collector wiring is high, so that the semiconductor layer can be formed uniformly. Further, since the current collector wiring does not project above the substrate, peeling of the semiconductor electrode can be prevented.

As in the third aspect of the invention described above, moreover, by forming a plurality of transparent electrode layers on the principal plane of the transparent substrate and forming a groove having an inclined wall surface between the transparent electrode layers, the measurement precision of resistance values of the transparent electrode layers can be enhanced, and the yield of the solar cell can be improved.

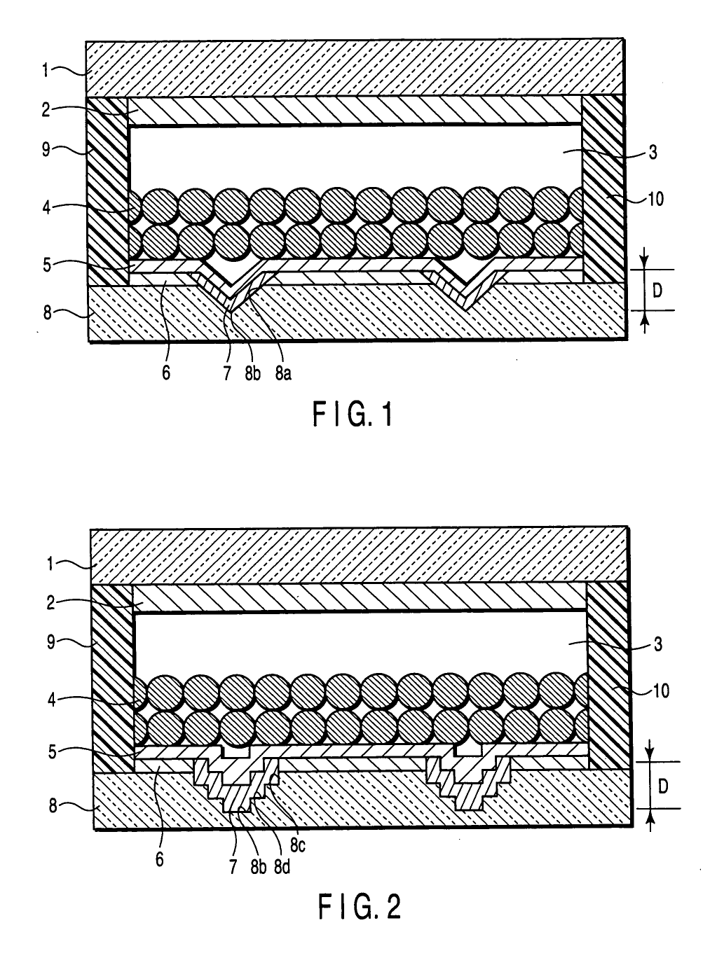

The photosensitized solar cell of the embodiment will be explained by referring to a sectional view in FIG. 1.

As shown in FIG. 1, a groove of V-section is formed on a principal plane of a transparent substrate 8. Such a groove has a wall surface 8a inclined in a V-form against the principal plane of the transparent substrate 8. Of the inner surface of the groove, the position of the maximum depth D is a bottom 8b. A current collector wiring 7 is formed in the inner surface of the groove. A transparent electrode layer 6 is formed in a portion other than the groove on the transparent substrate 8, that is, a non-groove forming portion on the principal plane of the transparent substrate 8. A peripheral edge of the current collector wiring 7 is bonded to the transparent electrode layer 6 surrounding this current collector wiring 7. A semiconductor layer 5 is formed on the current collector wiring 7 and transparent electrode layer 6, and a semiconductor electrode 4 is formed on the semiconductor layer 5. The semiconductor electrode 4 includes a mass of semiconductor particles, and has therefore a large surface area. A monomolecular layer of dye is formed on the surface of semiconductor particles of the semiconductor electrode 4. A conductive layer 2 is formed on a counter substrate 1. The conductive layer 2 is opposite to the semiconductor electrode 4. An electrolyte composition 3 is held in pores of the semiconductor particles of the transparent semiconductor electrode 4, and is interposed between the semiconductor electrode 4 and the conductive layer 2. In such a photosensitized solar cell, incident light coming from the transparent substrate 8 side is absorbed by the dye carried on the surface of the semiconductor electrode 4. The dye having absorbed the light hands over an electron to the semiconductor electrode 4, and the dye hands over a hole to the electrolyte layer 3, so that photoelectric conversion is carried out.

In FIG. 1, the section of the groove for forming the current collector wiring 7 is in V-form, and therefore even if the current collector wiring 7 is formed by sputtering, evaporation or plating, the current collector wiring 7 can be formed uniformly in the inner surface of the groove. As a result, since partial defects in the current collector wiring 7 can be reduced, faulty connection of the current collector wiring 7 and the transparent electrode layer 6 can be prevented. It is also effective to prevent breakage of the semiconductor layer 5, or penetration of the electrolyte composition into the current collector wiring 7. Assuming that the shape of the groove is not inclined in the wall surface, but the wall is vertical to the principal plane of the transparent substrate, when the current collector wiring 7 is formed by sputtering, evaporation or plating, the current collector wiring 7 hardly sticks to the wall surface. Therefore, conductive pass in the current collector wiring 7 deteriorates, which may result in faulty connection between the current collector wiring 7 and the transparent electrode layer 6. Further, since the current collector wiring 7 is formed very unevenly, its surface may largely be undulated and the semiconductor layer 5 may not be formed uniformly in the undulated surface of the current collector wiring 7. Owing to the V-section of a processed groove, the current collector wiring 7 and semiconductor layer 5 can be easily formed on the inner surface of the groove, the contact area between the semiconductor layer 5 and the transparent electrode layer 6 increases, and peeling resist effect of the semiconductor layer 5 can be obtained. By flattening the V-section bottom, a trapezoidal section can be formed.

Furthermore, as shown in FIG. 2, the section of the groove for forming the current collector wiring 7 can be formed in stairs. When formed in stairs, not only the same effects as in V-section are obtained, but also peeling of the current collector wiring 7 from the transparent substrate 8 can be suppressed more effectively, and it is further preferred. In the embodiment, a groove in stairs is shown an example shape of a groove having an inclined wall surface. Microscopically, stairs are not inclined slopes, but are composed of a vertical plane 8c and a parallel plane 8d to the substrate surface. However, by defining the height of one stair of stairs at less than 1 μm, the current collector wiring can be formed uniformly on a vertical plane of the groove, and hence it is allowed that a groove having a section in stairs can be included the groove having an inclined wall surface. Incidentally, the position of the maximum depth D in the inner surface of the groove is the bottom 8b.

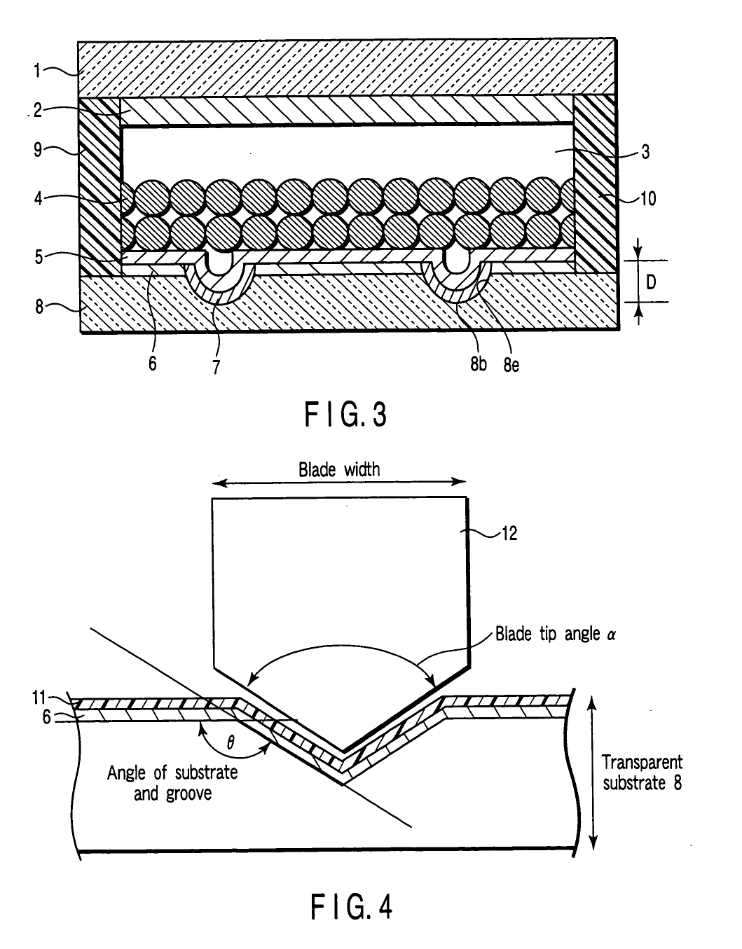

Moreover, as shown in FIG. 3, even when the section of the groove for forming the current collector wiring 7 in a U-form, since the wall surface 8e of the groove is inclined toward the transparent substrate 8, same effects are obtained. Further, by U-form, the bottom 8b of the groove does not have a sharp and discontinuous shape, and a bonding strength between the current collector wiring 7 and the groove can be increased. When the grooves of the same width are fabricated, the U-form groove depth can be shallower than the V-form groove depth, and a mechanical strength of the transparent substrate 8 can be increased.

In any shape, the maximum depth D of the groove is preferred to be about 50% or less of the transparent substrate thickness, more preferably 30% or less, the strength of the substrate can be assured. It is also preferred to keep the angle formed by the groove and the transparent substrate 8 at larger than 90 degrees and less than 180 degrees, more preferably 135 degree or more and less than 180 degrees. Herein, it is defined that the angle is 180 degrees when there is no depth at all in the transparent substrate. Further preferably, by forming grooves in stripes or lattice, the preferred width of the grooves is about 30 to 2000 μm, more preferably 50 to 200 μm, and the preferred interval between grooves is about 3 to 25 mm, more preferably 3 to 10 mm. In addition, a plastic substrate such as polyethylene terephthalate or polycarbonate can be used as the transparent substrate 8, and therefore it is easy to fabricate curved shape, it is inexpensive, degree of freedom of external design is high, it is hard to crack and leak liquid, the reaction area can be easily increased, the weight is light even if increased in size, roll-to-roll process is possible and suited to mass production, and many other effects are obtained.

A groove having an inclined wall surface is provided on the transparent substrate 8, the current collector wiring 7 is formed in the groove, and the transparent electrode layer 6 is formed in a portion other than the groove, for example, in the following method.

First, the transparent electrode layer 6 is formed on the entire surface of the transparent substrate 8 by sputtering or the like, and a resist is formed thereon by spin coating or the like. Thereafter, a groove is formed by using a diamond blade or the like having a blade tip shape suited to the desired groove shape. The current collector wiring 7 made of a metal material is formed by using a sputtering device or the like, the resist is peeled off, and the metal material is removed from the portion except for the groove. Alternatively, after performing a groove processing on the transparent substrate 8, the metal material can be formed on the entire surface of the transparent substrate 8 by evaporation or plating, and even if the portion other than the groove is removed by etching, the same structure can be obtained.

The composition of each component of the photosensitized solar cell of the embodiment will be specifically described below.

The transparent substrate 8 is preferred to be made of a substrate low in absorption in a light wavelength of 400 to 800 nm. The substrate material used for the transparent substrate 8 can be an inorganic material or an organic material. The inorganic material includes glass, and the organic material includes a plastic substrate such as a PET film or an acrylic substrate. The plastic substrate is hard to polish or flatten, and hence this embodiment is more effective.

The current collector wiring 7 is formed in the region having the groove provided therein, on the transparent substrate 8. The material of the current collector wiring layer 7 is not particularly specified, and, for example, gold, silver, copper or aluminum can be used. The material for forming the current collector wiring layer 7 is not limited to one type, but two or more kinds can be used.

In the region other than the groove, on the transparent substrate 8, the transparent electrode layer 6 is formed. The transparent electrode layer 6 can be formed of, for example, ITO, SnO₂, fluorine-doped SnO₂, etc.

The semiconductor layer 5 can be made of oxides of transition metals such as titanium, tin, zinc, zirconium, hafnium, strontium, indium, yttrium, lanthanum, vanadium, niobium, tantalum, chromium, molybdenum or tungsten, perovskite semiconductors such as SrTiO₃, CaTiO₃, BaTiO₃, MgTiO₃ or SrNb₂O₆, or their composite oxides or oxide mixtures, and GaN, etc. In particular, titanium oxide, tin oxide, indium oxide and zinc oxide are preferred. The semiconductor used in the semiconductor layer can either one kind or two or more kinds.

The thickness of the semiconductor layer 5 is preferred to be about 0.7 to 20 nm. The semiconductor layer 5 is intended to prevent counter flow of current from the transparent electrode layer 6 to the electrolyte layer 3, and to prevent the electrolyte in the electrolyte layer 3 from passing through the transparent electrode 6 to contact with the current collector wiring 7. If the thickness of the semiconductor layer 5 is less than 0.7 nm, the barrier effect on the electrolyte may be lowered. If the thickness of the semiconductor layer 5 exceeds 20 nm, the resistance is elevated, and the energy conversion efficiency of the solar cell may drop.

The semiconductor electrode 4 is preferred to contain a transparent semiconductor low in absorption in a visible light region. The semiconductor layer 4 is preferred to comprise a mass of fine particles that has a size of about 5 to 20 nm, or a porous material that contains the fine particles. Such a semiconductor is preferably realized by a metal oxide semiconductor. Specific examples include oxides of transition metals such as titanium, tin, zinc, zirconium, hafnium, strontium, indium, yttrium, lanthanum, vanadium, niobium, tantalum, chromium, molybdenum or tungsten, perovskite semiconductors such as SrTiO₃, CaTiO₃, BaTiO₃, MgTiO₃ or SrNb₂O₆, or their composite oxides or oxide mixtures, and GaN, etc. In particular, titanium oxide, tin oxide, indium oxide and zinc oxide are preferred. The semiconductor used in the semiconductor layer can either one kind or two or more kinds.

The semiconductor electrode 4 is preferred to contain the same semiconductor as the semiconductor layer 5. As a result, the bonding strength of the semiconductor electrode 4 and the semiconductor layer 5 can be enhanced.

The dye to be carried on the surface of the semiconductor electrode 4 includes, for example, ruthenium-tris type transition metal complex, ruthenium-bis type transition metal complex, osmium-tris type transition metal complex, osmium-bis type transition metal complex, ruthenium-cis-diaqua-bipyridyl complex, phthalocyanine, porphyrin, etc.

The dye can be carried on the semiconductor surface through ester bonding by immersing the semiconductor electrode 4 containing a semiconductor such as titania in a dye solution dissolved in a solvent such as ethanol.

It is desirable that the semiconductor layer 5 be formed as densely as possible to maintain the performance of a barrier against electrolyte. It is also desirable that the semiconductor layer 5 be formed as thin as possible without degrading the performance of the barrier in order to decrease in resistance. As a result, the effect of preventing counter flow of current from the transparent electrode layer 6 to the electrolyte layer 3 is further enhanced, together with the effect of preventing the electrolyte in the electrolyte layer 3 from reaching the current collector wiring 7. More preferably, the porosity of the semiconductor electrode 4 can be 40 to 60%. By defining the porosities of the semiconductor layer 5 and the semiconductor electrode 4 in these ranges, the energy conversion efficiency of the solar cell can be improved.

The counter substrate 1 is preferred to be made of a material small in absorption in a visible light region.

The conductive layer 2 provided on the surface of the counter substrate 1 is, for example, a metal such as platinum, gold and silver, a tin oxide film, a tin oxide film doped with fluorine, a zinc oxide film, or carbon. Considering the durability on the electrolyte, platinum is particularly preferred. Platinum can be adhered to the counter electrode 1 by electrochemical process or sputtering.

In the embodiment, the current collector wiring can be formed also on the counter substrate 1 having the conductive layer 2 provided on the surface in order to lower the resistivity. In such a case, on the conductive layer 2, the current collector wiring can be formed in stripe, lattice or other pattern by using a material of high durability with respect to the electrolyte such as platinum. Since a semiconductor electrode is not formed on the counter substrate 1, the current collector wiring can be formed in a convex shape or a groove may not be formed. From the viewpoint of effective use of light, the current collector wiring 7 provided on the transparent substrate 8 and the current collector wiring provided on the counter electrode are preferred to be of the same pattern.

The electrolyte composition contained in the electrolyte layer 3 is preferred to contain a reversible redox couple composed of I⁻ and I₃⁻. The reversible redox couple can be supplied from mixture of iodine (I₂) and iodide.

The above-described redox couple is preferred to exhibit a redox potential lower by 0.1 to 0.6 V than an oxidation potential of a dye. In the redox couple exhibiting a redox potential lower by 0.1 to 0.6 V than an oxidation potential of a dye, for example, the reducing species such as I⁻ can receive a hole from an oxidized dye. Since such a redox couple is contained in the electrolyte layer 3, the electric charge transfer between the semiconductor electrode 4 and the conductive layer 2 can be promoted, and the open-circuit voltage can be enhanced.

Molten salts of iodide include, for example, iodides of heterocyclic compound having nitrogen such as imidazolium salt, pyridinium salt, quaternary ammonium salt, pyrrolidinium salt, pyrazolidinium salt, isothiazolidinium salt, and isoxazolidinium salt.

Examples of the molten salt of iodine are 1,3-dimethyl imidazolium iodide, 1-ethyl-3-methyl imidazolium iodide, 1-methyl-3-propyl imidazolium iodide, 1-methy-3-pentyl imidazolium iodide, 1-methyl-3-isopentyl imidazolium iodide, 1-methyl-3-hexyl imidazolium iodide, 1-methyl-3-isohexyl (branched) imidazolium iodide, 1-methyl-3-ethyl imidazolium iodide, 1,2-dimethyl-3-propyl imidazole iodide, 1-ethyl-3-isopropyl imidazolium iodide, 1-propyl-3-propyl imidazolium iodide, pyrrolidinium iodide, etc. Such molten salts of iodides can be used either alone or in combination of two or more kinds. The content of molten salt of iodide in the electrolyte layer is preferred to be about 0.005 mol/L or more and 7 mol/L or less. If less than 0.005 mol/L, the effect cannot be obtained sufficiently. If exceeding 7 mol/L, the viscosity is too high, and the ion conductivity may be lowered extremely.

The electrolyte composition is preferred to contain iodine, and its content is preferred to be about 0.01 mol/L or more and 3 mol/L or less. Iodine is mixed with iodide in the electrolyte layer 3, and acts as a reversible redox couple. Therefore, if the content of iodine is less than 0.01 mol/L, an oxidant is insufficient in the redox couple, and it is hard to transfer electric charge. If the content of iodine exceeds 3 mol/L, light absorption of a solution increases, and light may not be given sufficiently to the semiconductor electrode 4. The content of iodine is more preferably 0.03 mol/L or more and 1.0 mol/L or less.

The electrolyte composition can be either liquid or gel, and an organic solvent can be also contained. Due to an organic solvent being contained, the viscosity of the electrolyte composition can be further lowered, and it is easier to permeate into the semiconductor electrode 4.

Usable organic solvents include cyclic carbonate such as ethylene carbonate (EC) and propylene carbonate (PC); chain carbonate such as dimethyl carbonate, methyl ethyl carbonate, and diethyl carbonate; γ-butyrolactone, acetonitrile, methyl propionate, ethyl propionate, and others. Further examples include cyclic ether such as tetrahydrofuran and 2-methyl tetrahydrofuran; chain ether such as dimethoxy ethane and diethoxy ethane; and nitrile solvents such as acetonitrile, propionitrile, glutaronitrile, and methoxy propionitrile. These organic solvents can be used either alone or in combination of two or more kinds.

The content of the organic solvent is not specified, but is preferred to be 30 wt. % or less in the electrolyte composition. If the content of the organic solvent exceeds 30 wt. %, the performance may deteriorate due to evaporation. The content of the organic solvent is preferred to be 0 wt. % or more and 30 wt. % or less.

Referring now to the drawings, more specific examples will be described below.

### EXAMPLE 1

As shown in FIG. 1, on a transparent substrate 8 made of polyethylene terephthalate (PET) resin of 20 cm×15 cm size in a thickness of 100 μm, a transparent conductive oxide film (ITO) made of 90% of tin oxide and 10% of indium oxide was formed as a transparent electrode layer 6 by sputtering in a thickness of 50 nm. On the transparent electrode layer 6, a resist obtained by dissolving polyvinyl benzene in a solvent of xylene at 20% was formed by spin coating, and dried at 100° C.

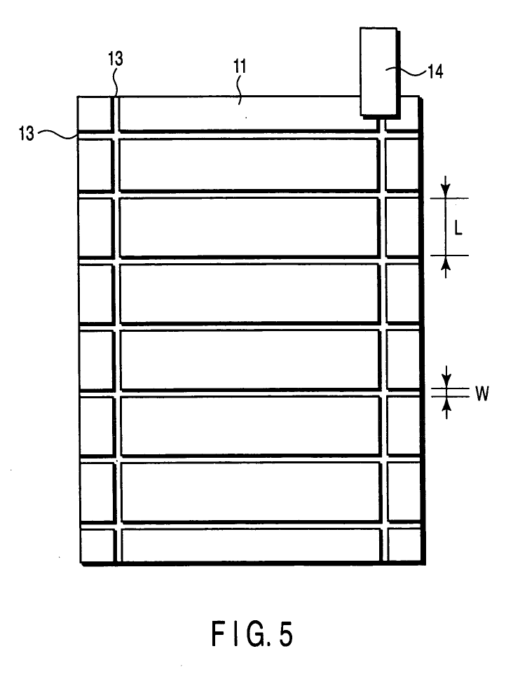

As shown in FIG. 4, mounting on a dicing saw with the side on which the transparent electrode layer 6 and resist 11 are formed upside, grooves were processed on the upper surface of the transparent substrate 8 by using a diamond blade 12 of 100 μm in thickness, having a V-form leading end whose angle α is 90 degrees. As shown in FIG. 5, the grooves 13 were formed parallel the lateral direction (shorter side direction) of the transparent substrate 6 at pitch interval L of 10 mm. Grooves intersecting with these grooves were also formed parallel to the longitudinal direction of the transparent substrate 6. The maximum depth D of the grooves was 50 μm. The groove width W was 100 μm. The grooves 13 have the sectional shape such that the angle θ between the upper surface of the transparent substrate 8 and the groove wall surface was about 135 degrees. A lead 14 in FIG. 5 is intended to be connected to one end of a current collector wiring 7 after removing the resist 11.

Then, a Cr layer of 0.1 μm and an Au layer of 2 μm were formed by a sputtering device, the resist 11 was removed by acetone, and the current collector wiring 7 was obtained. On the upper surface of the transparent substrate 8, ITO was formed again as a transparent conductive film (not shown) in a thickness of 50 nm, and TiO₂ was formed in a thickness of 10 nm as a semiconductor layer 5 serving as a barrier layer of corrosion by an electrolyte.

Titania paste was prepared by kneading high purity titanium oxide powder with average primary particle size of 30 μm, nitric acid, purified water, and surfactant. On the upper surface of the transparent substrate 8 having the semiconductor layer 5 formed thereon, the titania paste was printed by screen printing, and baked at 120° C., and an n-type semiconductor electrode made of titanium oxide of 2 μm in thickness was formed. By repeating this printing and baking process, a semiconductor electrode 4 having thickness of 10 μm and roughness factor of 2000 was formed. The porosity of the semiconductor electrode 4 was 50%.

By dissolving cis-bis(cyocyanato)-N,N-bis(2,2′-dipyridyl-4,4′-dicarboxylic)-ruthenium (II) dihydrate) in dry ethanol, a dry ethanol solution of 3×10⁻⁴ M was prepared. This solution was held at temperature of about 90° C., and the n-type semiconductor electrode was immersed for 3 hours. Thereafter, by pulling up in argon stream, a ruthenium complex as a dye was carried on the surface of the n-type semiconductor electrode 4.

Next, on another transparent resin substrate, a conductive layer 2 made of a platinum layer of 20 nm and an ITO conductive film of 50 nm was formed by sputtering, and a counter substrate 1 was obtained.

Resin spherical beads (spacer) of 30 μm in diameter was placed between the transparent substrate 8 and the counter substrate 1. The two substrates were fixed to each other at room temperature by applying an epoxy resin 9 to a peripheral portion except an electrolysis solution inlet. By this operation, a dye-sentized solar cell unit was obtained.

The electrolyte composition was prepared as follows. 0.5M of tetrapropyl ammonium iodide, 0.02M of potassium iodide, and 0.2M of iodine were dissolved in 1-methyl-3-propyl imidazolium iodide, and an electrolyte solution (A) was prepared. In 10 g of this electrolyte solution (A), 0.3 g of poly(4-vinyl pyridine) as a compound containing N was dissolved together with 1.1 g of water. By dissolving 0.3 g of 1,6-dibromohexane as organic bromide in the obtained solution, a gel electrolyte precursor was obtained. The gel electrolyte precursor was injected into an opening of the dye-sentized solar cell unit. The gel electrolyte precursor permeated into the n-type semiconductor electrode 4, and was also injected between the n-type semiconductor electrode 4 and the conductive layer 2. In succession, by sealing the opening of the dye-sentized solar cell unit with an epoxy resin 10, and by heating for 30 minutes at 60° C. on a hot plate, a photovoltaic device, that is, a photosensitized solar cell was manufactured.

By using this photosensitized solar cell, when the energy conversion efficiency of the solar cell was measured by using a quasi-solar light of 100 mW/cm², a conversion efficiency of 3.5% was obtained in average on the effective surface area. During process or after power generation test, no breakage of the current collector wiring 7 was noted. When microscopic observation was performed on the groove, peeling of the semiconductor electrode 4 having the dye carried thereon was only less than 1% of the groove inner surface area.

Corrosion due to the electrolyte layer 3 of the current collector wiring 7 was not also found. It has been hence known effective to avoid defective conduction by defining the angle formed by the substrate upper surface and the groove wall surface at about 135 degrees. The TiO₂ barrier layer as the semiconductor layer 5 was formed evenly on the groove inner surface.

### EXAMPLE 2

A photosensitized solar cell was manufactured by using the same materials and methods as in Example 1, except that grooves were processed in a transparent substrate 8 by using a diamond blade of 50 μm in thickness with leading end shape in stairs as shown in FIG. 2. The angle formed by the upper surface of the transparent substrate 8 and the stair section of the groove was about 135 degrees.

Similarly, when the energy conversion efficiency was measured, 3.3% was obtained. The microscopic observation of the groove disclosed peeling of the semiconductor electrode 4 of only less than 0.5% of the groove inner surface area, and the stair processing of the groove has proved improvement of peeling strength of the transparent substrate 8 and the current collector wiring 7.

### EXAMPLE 3

A photosensitized solar cell was manufactured by using the same materials and methods as in Example 1, except that grooves were processed in a transparent substrate 8 by using a diamond blade that has a thickness of 100 μm and a U-form leading end as shown in FIG. 3. The maximum depth of the groove was 15 μm. The angle formed by the upper surface of the transparent substrate 8 and the tangent of the groove section was about 150 to 160 degrees.

Similarly, when the energy conversion efficiency was measured, 3.6% was obtained. The microscopic observation of the groove disclosed peeling of the semiconductor electrode 4 of only less than 1% of the groove inner surface area. The transparent substrate 8 was less in deflection, and the mechanical strength of the solar cell was increased by reducing the depth of the groove.

### EXAMPLE 4

On a transparent substrate 8 made of polyethylene terephthalate (PET) resin of 30 cm×21 cm size in a thickness of 100 μm, a transparent conductive oxide film (FTO) made of tin oxide doped with fluorine was formed by sputtering, and a transparent electrode layer 6 was formed in a thickness of 50 nm. On the transparent electrode layer 6, a resist obtained by dissolving polyvinyl benzene in a solvent of xylene at 20% was formed by spin coating, and dried at 100° C.

Mounting on a dicing saw with the side on which the transparent electrode layer 6 and resist were formed upside, grooves were processed on the upper surface of the transparent substrate 8 by using a diamond blade of 100 μm in thickness, having a V-form leading end whose angle α is 135 degrees. The grooves were formed parallel the shorter side direction of the transparent substrate 6 at pitch interval L of 10 mm. Grooves intersecting with these grooves were also formed parallel to the longitudinal direction of the transparent substrate 6. The maximum depth D of the grooves was 17 μm. Further, the grooves have the sectional shape such that the angle between the upper surface of the transparent substrate 8 and the groove wall surface was about 158 degrees.

Then, a Ti layer of 0.05 μm and an Au layer of 2 μm were formed by a sputtering device, the resist was removed by acetone, and a current collector wiring 7 was obtained. On the upper surface of the transparent substrate 8, FTO was formed again as a transparent conductive film (not shown) in a thickness of 30 nm, and TiO₂ was formed in a thickness of 20 nm as a semiconductor layer 5 serving as a barrier layer of corrosion by an electrolyte.

Thereafter, a dye-sentized solar cell was manufactured in the same manner as in Example 1, including the steps of forming the n-type semiconductor layer, carrying the dye, fabricating the counter substrate, arranging the spacer, sealing, preparing the electrolyte solution, injecting, and sealing the opening.

Using this dye-sentized solar cell, when the energy conversion efficiency of the solar cell was measured by using a quasi-solar light of 100 mW/cm², a conversion efficiency of 3.6% was obtained in average on the effective surface area. During process or after power generation test, no breakage of the current collector wiring 7 was noted. Microscopic observation of the groove disclosed peeling of the semiconductor electrode 4 of only less than 0.5% of the groove inner surface area.

Corrosion due to the electrolyte layer 3 of the current collector wiring 7 was not also found. It has been hence known effective to avoid defective conduction by defining the angle formed by the substrate upper surface and the groove wall surface at about 158 degrees. There was no defect in the semiconductor layer 5 made of TiO₂ barrier layer provided on the groove inner surface.

### EXAMPLE 5

On a transparent substrate 8 made of polyethylene terephthalate (PET) resin of 20 cm×15 cm size in a thickness of 100 μm, a transparent conductive oxide film (ITO) made of 90% of tin oxide and 10% of indium oxide was formed by sputtering, and a transparent electrode layer 6 was formed in a thickness of 50 nm. On the transparent electrode layer 6, a resist obtained by dissolving polyvinyl benzene in a solvent of xylene at 20% was formed by spin coating, and dried at 100° C.

Mounting on a dicing saw with the side on which the transparent electrode layer 6 and resist were formed upside, grooves were processed on the upper surface of the transparent substrate 8 by using a diamond blade of 200 μm in thickness, having a V-form leading end whose angle α is 155 degrees. The grooves were formed parallel the shorter side direction of the transparent substrate 6 at pitch interval L of 10 mm. Grooves intersecting with these grooves were also formed parallel to the longitudinal direction of the transparent substrate 6. The maximum depth D of the grooves was 15 μm. The grooves have the sectional shape such that the angle θ between the upper surface of the transparent substrate 8 and the groove wall surface was about 168 degrees.

Then, a Ti layer of 0.05 μm and an Au layer of 2 μm were formed by a sputtering device, the resist was removed by acetone, and a current collector wiring 7 was obtained. On the upper surface of the transparent substrate 8, ITO was formed again as a transparent conductive film (not shown) in a thickness of 30 nm, and TiO₂ was formed in a thickness of 30 nm as a semiconductor layer 5 serving as a barrier layer of corrosion by an electrolyte.

Thereafter, a dye-sentized solar cell was manufactured in the same manner as in Example 1, including the steps of forming the n-type semiconductor layer, carrying the dye, fabricating the counter substrate, arranging the spacer, sealing, preparing the electrolyte solution, injecting, and sealing the opening.

Using this dye-sentized solar cell, when the energy conversion efficiency of the solar cell was measured by using a quasi-solar light of 100 mW/cm², a conversion efficiency of 3.1% was obtained in average on the effective surface area. As compared with Example 1, the conversion efficiency was slightly lowered, and it was estimated because the width of groove fluctuated as a result of processing of an extremely shallow groove by using a dicer blade whose leading end angle is wide, and fluctuations also occurred in the resistance value of the metal layer in the groove. To suppress such fluctuations, it seems effective to manufacture a cell increased in the depth of groove. However, when a deep groove was formed by using a blade whose leading end angle is wide, the width of the groove was extremely increased. As a result, the incident light was shielded, and the effective area contributing to power generation was decreased, thereby leading to reduction of conversion efficiency. During process or after power generation test, no breakage of the current collector wiring 7 was noted. Microscopic observation of the groove disclosed peeling of the semiconductor electrode 4 of only less than 0.5% of the groove inner surface area.

Corrosion due to the electrolyte layer 3 of the current collector wiring 7 was not also found. It has been hence known effective to avoid defective conduction by defining the angle formed by the substrate upper surface and the groove wall surface at about 168 degrees. The TiO₂ barrier layer as the semiconductor layer 5 was formed uniformly on the groove inner surface.

### EXAMPLE 6

On a transparent substrate 8 made of polyethylene terephthalate (PET) resin of 20 cm×15 cm size in a thickness of 100 μm, a transparent conductive oxide film (ITO) made of 90% of tin oxide and 10% of indium oxide was formed by sputtering, and a transparent electrode layer 6 was formed in a thickness of 50 nm. On the transparent electrode layer 6, a resist obtained by dissolving polyvinyl benzene in a solvent of xylene at 20% was formed by spin coating, and dried at 100° C.

Mounting on a dicing saw with the side on which the transparent electrode layer 6 and resist were formed upside, grooves were processed on the upper surface of the transparent substrate 8 by using a diamond blade of 80 μm in thickness, having a V-form leading end whose angle α is 60 degrees. The grooves were formed parallel the shorter side direction of the transparent substrate 6 at pitch interval L of 10 mm. Grooves intersecting with these grooves were also formed parallel to the longitudinal direction of the transparent substrate 6. The maximum depth D of the grooves was 65 μm. The grooves have the sectional shape such that the angle θ between the upper surface of the transparent substrate 8 and the groove wall surface was about 120 degrees.

Then, a Cr layer of 0.1 μm and an Au layer of 2 μm were formed by a sputtering device, the resist was removed by acetone, and a current collector wiring 7 was obtained. On the upper surface of the transparent substrate 8, ITO was formed again as a transparent conductive film (not shown) in a thickness of 40 nm, and TiO₂ was formed in a thickness of 20 nm as a semiconductor layer 5 serving as a barrier layer of corrosion by an electrolyte.

Thereafter, a dye-sentized solar cell was manufactured in the same manner as in Example 1, including the steps of forming the n-type semiconductor layer, carrying the dye, fabricating the counter substrate, arranging the spacer, sealing, preparing the electrolyte solution, injecting, and sealing the opening.

Using this dye-sentized solar cell, when the energy conversion efficiency of the solar cell was measured by using a quasi-solar light of 100 mW/cm², a conversion efficiency of 2.9% was obtained in average on the effective surface area. As compared with Example 1, the conversion efficiency was slightly lowered, and it was estimated because the width of groove was narrowed by using a dicer blade whose leading end angle is small, and the resistance value of the metal layer formed in the groove was elevated. To suppress such elevation, it seems effective to manufacture a cell increased in the depth of the groove. However, when a deep groove was formed by using a blade whose leading end angle is small, the deep of the groove was extremely increased. As a result, although the resistance value of the metal wiring can be kept low, the strength was lowered as a result of a deep groove formed in the plastic substrate. Therefore, the ITO film was cracked to increase the resistance of the substrate, or the substrate was cracked to reduce the reliability of the cell, thereby leading to decline of conversion efficiency. During process or after power generation test, no breakage of the current collector wiring 7 was noted. Microscopic observation of the groove disclosed peeling of the semiconductor electrode 4 of only less than 0.5% of the groove inner surface area.

Corrosion due to the electrolyte layer 3 of the current collector wiring 7 was not also found. It has been hence known effective to avoid defective conduction by defining the angle formed by the substrate upper surface and the groove wall surface at about 120 degrees. The TiO₂ barrier layer as the semiconductor layer 5 was formed on the groove inner surface without defects.

### EXAMPLE 7

Zinc oxide paste was prepared by kneading high purity zinc oxide powder having average primary particle size of 30 μm, nitric acid, purified water, and surfactant. On the upper surface of the transparent substrate 8 having the semiconductor layer 5 formed thereon, the zinc oxide paste was printed by screen printing, and baked at 120° C., and an n-type semiconductor electrode that contains zinc oxide and has a thickness of 2 μm was formed. By repeating this printing and baking process, a semiconductor electrode 4 having thickness of 10 μm and roughness factor of 2000 was formed.

A dye-sentized solar cell was manufactured in the same manner as in Example 1 except for the above process.

Using this dye-sentized solar cell, when the energy conversion efficiency of the solar cell was measured by using a quasi-solar light of 100 mW/cm², a conversion efficiency of 2.1% was obtained in average on the effective surface area. During process or after power generation test, no breakage of the current collector wiring 7 was noted. Microscopic observation of the groove disclosed peeling of the semiconductor electrode 4 of only less than 2% of the groove inner surface area.

Corrosion due to the electrolyte layer 3 of the current collector wiring 7 was not also found. It has been hence known effective to avoid defective conduction by defining the angle formed by the substrate upper surface and the groove wall surface at about 135 degrees also in the zinc oxide semiconductor layer.

### Comparative Example 1

A photosensitized solar cell was manufactured by using the same materials and methods as in Example 1, except that the transparent substrate had no groove and no current collector wiring. Similarly, when the energy conversion efficiency was measured, 0.3% was obtained. Because of no current collector wiring, it has been confirmed that the power generation efficiency in wide electrode area is extremely lowered.

### Comparative Example 2

Grooves were processed on the upper surface of a transparent substrate by using a diamond blade that has a thickness of 50 μm and a rectangular leading end. The maximum depth of the groove was 15 μm. The grooves had a sectional shape such that the angle between the upper surface of the transparent substrate and the groove wall surface was 90 degrees.

Similarly, when the energy conversion efficiency was measured, 1.2% was obtained. Microscopic observation of the groove disclosed peeling of the semiconductor electrode of only less than 3% of the groove inner surface area. Defective conduction was frequently observed between the transparent electrode and the current collector wiring. Since the angle between the groove wall surface and the transparent substrate was 90 degrees, failure of sticking of the current collector wiring to the groove wall surface was recognized.

These results are summarized in Table 1. Table 1 shows the groove sectional shape, the angle formed by the transparent substrate and the groove wall surface, the maximum depth of the groove, the groove pitch interval, the groove width, the energy conversion efficiency, and the peeling rate of the semiconductor electrode in Examples 1 to 7 and Comparative examples 1 and 2.

TABLE 1

| | | Angle of | Maximum | Groove | | Energy | |
|---|---|---|---|---|---|---|---|
| | | substrate and | depth D | pitch | Groove | conversion | Peeling of |
| | Groove | groove wall | of groove | interval L | width W | efficiency | semiconductor |
| | shape | (deg.) | (μm) | (mm) | (μm) | (%) | electrode (%) |
| Example 1 | V-form | 135 | 50 | 10 | 100 | 3.5 | Less than 1% |
| Example 2 | Stairs | 135 | 50 | 10 | 100 | 3.3 | Less than 0.5% |
| Example 3 | U-form | 150-160 | 15 | 10 | 110 | 3.6 | Less than 1% |
| Example 4 | V-form | 158 | 17 | 10 | 70 | 3.6 | Less than 0.5% |
| Example 5 | V-form | 168 | 15 | 10 | 80 | 3.1 | Less than 0.5% |
| Example 6 | V-form | 120 | 65 | 10 | 75 | 2.9 | Less than 0.5% |
| Example 7 | V-form | 135 | 50 | 10 | 100 | 2.1 | Less than 2% |
| Comparative | Not formed | — | — | — | — | 0.3 | — |
| Example 1 | | | | | | | |
| Comparative | Rectangular | 90 | 15 | 10 | 50 | 1.2 | 3% |
| Example 2 | | | | | | | |

Comparison between Examples 1 to 7 and Comparative example 2 in Table 1 discloses that a energy conversion efficiency in a large electrode area is higher than Comparative example 2 having a wall vertical to the transparent substrate, by setting parallel or inclining at least part of the wall of the groove to the transparent substrate as in Examples 1 to 7. By comparison of Examples 1 and 4 to 6, it is understood that a higher energy conversion efficiency is obtained in the solar batteries of Examples 1, 4 and 5 of which angle formed by the principal plane of the transparent substrate and the groove wall surface is 135 degrees or more and less than 180 degrees as compared with Example 6. Comparison of Example 1 and Example 7 discloses that the energy conversion efficiency is higher and peeling of the semiconductor electrode is less in the solar cell of Example 1 containing titanium oxide as the semiconductor contained in the semiconductor layer and semiconductor electrode, as compared with Example 7 using zinc oxide as the semiconductor for the semiconductor electrode.

As described herein, the photosensitized solar cells of the Examples are high in energy conversion efficiency even if an electrode area is large, and also high in the reliability of the semiconductor layer and semiconductor electrode formed on the current collector wiring and transparent substrate. In each Example, the sunlight is supposed to enter from the n-type semiconductor electrode side, but the invention is not limited to this example alone. In the case of a solar cell designed to make the sunlight enter from the counter electrode side, same effects can be obtained by using the same structure of the embodiment according to the invention.

Hence, the invention provides a photosensitized solar cell capable of obtaining a high energy conversion efficiency, and a method of manufacturing the same.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A photosensitized solar cell comprising:
a transparent substrate having a groove with an inclined wall surface;
a current collector wiring made of metal, provided on the inclined wall surface of the groove;
a transparent electrode layer provided in a region other than the groove on the transparent substrate;
a semiconductor layer provided on the transparent electrode layer and current collector wiring;
a semiconductor electrode provided on the semiconductor layer, and carrying a dye;
a counter substrate;
a conductive layer provided on the counter substrate and facing the semiconductor electrode; and
an electrolyte layer provided between the semiconductor electrode and the conductive layer, and containing iodine and iodide.

2. The photosensitized solar cell according to claim 1, wherein a section of the groove is V-form, U-form, or stair form.

3. A photosensitized solar cell comprising:
a transparent substrate;
a groove formed in a surface of the transparent substrate, and having a wall surface and a bottom surface, at least a part of the wall surface being parallel to or inclined to the surface of the transparent substrate;
a current collector wiring made of metal, provided on the bottom surface and wall surface of the groove;
a transparent electrode layer provided in a non-groove region on the surface of the transparent substrate;
a counter substrate;
a conductive layer provided on the counter substrate;
a semiconductor electrode provided between the conductive layer and the transparent electrode layer, and carrying a dye; and
an electrolyte layer provided between the semiconductor electrode and the conductive layer.

4. The photosensitized solar cell according to claim 3, wherein a section of the groove is V-form, U-form, stair form, or trapezoidal form.

5. The photosensitized solar cell according to claim 3, wherein an angle formed by the surface of the transparent substrate and the wall surface of the groove is 90 degrees or more and less than 180 degrees.

6. The photosensitized solar cell according to claim 3, wherein a maximum depth of the groove is 50% or less of a thickness of the transparent substrate.

7. The photosensitized solar cell according to claim 3, wherein a width of the groove is 30 μm or more and 2000 μm or less.

8. The photosensitized solar cell according to claim 3, wherein an interval of the grooves is 3 mm or more and 25 mm or less.

9. The photosensitized solar cell according to claim 3, wherein the metal of the current collector wiring is at least one kind metal selected from the group consisting of gold, silver, copper and aluminum.

10. The photosensitized solar cell according to claim 3, further comprising a semiconductor layer formed on the transparent electrode layer and the current collector wiring.

11. The photosensitized solar cell according to claim 10, wherein a porosity of the semiconductor layer is 70% or more and 80% or less.

12. The photosensitized solar cell according to claim 3, wherein the electrolyte layer contains iodine and iodide.

13. A photosensitized solar cell comprising:
a transparent substrate;
a plurality of transparent electrode layers provided on the transparent substrate,
grooves formed on the transparent substrate and between the transparent electrode layers, and having an inclined wall surface;
a current collector wiring made of metal, provided on the inclined wall surface of the groove;
a semiconductor layer which covers the transparent electrode layers and the current collector wiring;
a semiconductor particle layer provided on the semiconductor layer, and carrying a dye;
a counter substrate;
a conductive layer provided on the counter substrate, and facing the semiconductor particle layer; and
an electrolyte layer provided between the semiconductor particle layer and the conductive layer, and containing iodine and iodide.

14. The photosensitized solar cell according to claim 13, wherein a section of the groove is V-form, U-form, stair form, or trapezoidal form.

15. A method of manufacturing a photosensitized solar cell, comprising:
forming a transparent electrode layer on a transparent substrate;
forming a groove having an inclined wall surface on the transparent electrode layer;
forming a current collector wiring made of metal on the inclined wall surface of the groove;
forming a semiconductor layer on the groove and the transparent electrode layer;
forming a semiconductor electrode on the semiconductor layer;
carrying a dye on the semiconductor electrode;
forming a conductive layer on a counter substrate; and
forming an electrolyte layer between the semiconductor electrode and the conductive layer, and the electrolyte layer containing iodine and iodide.

16. The method of manufacturing a photosensitized solar cell, according to claim 15, wherein a section of the groove is V-form, U-form, or stair form.
